(19) United States
(12) Patent Application Publication
(10) Pub. No.: US 2026/0013307 A1
(43) Pub. Date: Jan. 8, 2026

(54) DISPLAY DEVICE, RESIN COMPOSITION, METHOD OF MANUFACTURING DISPLAY DEVICE, AND ELECTRONIC DEVICE COMPRISING DISPLAY DEVICE

(71) Applicant: Samsung Display Co., Ltd., Yongin-Si (KR)

(72) Inventors: Ki Nyeng KANG, Yongin-si (KR); Jong Hyuk KANG, Yongin-si (KR); Ki Beom LEE, Yongin-si (KR); Keun Kyu SONG, Yongin-si (KR)

(21) Appl. No.: 19/094,205

(22) Filed: Mar. 28, 2025

(30) Foreign Application Priority Data
Jul. 3, 2024 (KR) 10-2024-0087529

(51) Int. Cl. H10H 29/85; H01L 25/075; H10H 29/01

(52) U.S. Cl. CPC H10H 29/857; H01L 25/0753; H10H 29/0364

(57) ABSTRACT

According to an embodiment of the disclosure, a display device, a resin composition, a method of manufacturing the display device, and an electronic device comprising the display device are provided. The display device includes a base layer, a conductive layer on the base layer, a via layer covering the conductive layer, an electrode layer disposed on the via layer and including a first electrode and a second electrode spaced apart from each other by a separation distance, and a light-emitting element between the first electrode and the second electrode. The conductive layer may be overlapped with the electrode layer in an overlapping area in a plane view. The via layer may have a medium thickness, which is equal to or more than 2 μm, in the overlapping area. The separation distance may be equal to or more than 3.0 μm.

### CROSS-REFERENCE TO RELATED APPLICATION

This application claims priority to Korean Patent Application No. 10-2024-0087529, filed on Jul. 3, 2024, in the Korean Intellectual Property Office, the entire contents of which are incorporated herein by reference.

### BACKGROUND

### 1. Field

The present disclosure relates to a display device, a resin composition, a method of manufacturing the display device, and an electronic device comprising the display device.

### 2. Description of the Related Art

Recently, as interest in information display has increased, research and development on display devices is continuously being performed.

### SUMMARY

The present disclosure is to provide a display device, a resin composition, a method of manufacturing the display device, and an electronic device comprising the display device, in which a thickness of a via layer may be appropriately controlled.

The present disclosure is to provide a display device, a resin composition, a method of manufacturing the display device, and an electronic device comprising the display device, in which an interval between alignment electrodes on a via layer may be appropriately controlled to have excellent display quality.

According to an embodiment of the present disclosure, a display device includes a base layer, a conductive layer on the base layer, a via layer covering the conductive layer, an electrode layer disposed on the via layer and including a first electrode and a second electrode spaced apart from each other by a separation distance, and a light-emitting element between the first electrode and the second electrode. The conductive layer and the electrode layer may overlap each other in an overlapping area in a plane view. The via layer may have a medium thickness, which is equal to or more than 2 μm, in the overlapping area. The separation distance may be equal to or more than 3.0 μm.

According to an embodiment, an upper surface of the conductive layer may be in direct contact with the via layer.

According to an embodiment, the conductive layer and the electrode layer may not overlap each other in a non-overlapping area in a plane view. The via layer may include a flat surface formed in the overlapping area and the non-overlapping area.

According to an embodiment, the medium thickness may be in a range of 2 μm to 5 μm.

According to an embodiment, the separation distance may be in a range of 3.2 μm and 3.5 μm.

According to an embodiment, the display device may further include a first connection electrode electrically connecting the first electrode to the light-emitting element, and a second connection electrode electrically connecting the second electrode to the light-emitting element.

According to an embodiment of the present disclosure, a resin composition includes a resin material including an acrylic resin, a monomer including a multifunctional acrylic monomer, a photoinitiator, and a solvent. An amount of the resin material may be in a range from about 3 wt % to about 10 wt % with respect to an entirety of the resin composition. An amount of the monomer may be in a range from about 2 wt % to about 5 wt % with respect to the entirety of the resin composition.

According to an embodiment, the resin material may have a molecular weight ranging from about 5,000 g/mol to about 15,000 g/mol in average.

According to an embodiment, the monomer may include at least one selected from a group consisting of ethoxylated flrorene type diacrylate, phenylthioethyl acrylate, cumyl phonoxy ethyl acrylate, o-phenylphenoxy ethyl acrylate, and m-phonoxy benzyl acrylate, and an amount of the monomer may be in a range from about 2 wt % to about 5 wt % with respect to the entirety of the resin composition.

According to an embodiment, the photoinitiator may include at least one selected from a group consisting of a phosphine oxide compound and a metallocene compound, and an amount of the photoinitiator may be in a range from about 1 wt % to 3 about wt % with respect to the entirety of the resin composition.

According to an embodiment, the resin composition may further include a silicone surfactant. The solvent may include at least one selected from a group consisting of methyl 3-methoxypropionate and propylene glycol methyl ether acetate, and an amount of the solvent may be in a range from about 82 wt % to about 94 wt % with respect to the entirety of the resin composition.

According to an embodiment of the present disclosure, a method of manufacturing a display device includes arranging a conductive layer on a base layer, depositing a base via layer which covers the conductive layer and includes a resin composition, forming a via layer through a polymerization reaction of the base via layer, patterning a first electrode and a second electrode on the via layer, and arranging a light-emitting element between the first electrode and the second electrode. The resin composition may include a resin material including an acrylic resin, a monomer including a multifunctional acrylic monomer, a photoinitiator, and a solvent. An amount of the resin material may be in a range from about 3 wt % to about 10 wt % with respect to an entirety of the resin composition. An amount of the monomer may be in a range from about 2 wt % to about 5 wt % with respect to the entirety of the resin composition.

According to an embodiment, the arranging of the light-emitting elements may include supplying ink including the light-emitting element and a solvent onto the base layer, generating an electric field between the first electrode and the second electrode, and aligning the light-emitting element between the first electrode and the second electrode based on the electric field.

According to an embodiment, the resin material may have a molecular weight ranging from about 5,000 g/mol to about 15,000 g/mol in average. The monomer may include at least one selected from a group consisting of ethoxylated flrorene type diacrylate, phenylthioethyl acrylate, cumyl phonoxy ethyl acrylate, o-phenylphenoxy ethyl acrylate, and m-phonoxy benzyl acrylate, and an amount of the monomer may be in a range from about 2 wt % to about 5 wt % with respect to the entirety of the resin composition.

According to an embodiment, the photoinitiator may include at least one selected from a group consisting of a phosphine oxide compound and a metallocene compound, and an amount of the photoinitiator may be in a range from about 1 wt % to 3 about wt % with respect to the entirety of the resin composition. The resin composition may further include a silicone surfactant. The solvent may include at least one selected from a group consisting of methyl 3-methoxypropionate and propylene glycol methyl ether acetate, and an amount of the solvent may be in a range from about 82 wt % to about 94 wt % with respect to the entirety of the resin composition.

According to an embodiment of the present disclosure, an electronic device may comprising: a processor configured to provide input image data; a display device configured to display an image based on the input image data; and a power supply configured to supply power to the display device. The display device may comprises: a base layer; a conductive layer on the base layer; a via layer covering the conductive layer; an electrode layer disposed on the via layer, and including a first electrode and a second electrode spaced apart from each other by a separation distance; and a light-emitting element disposed on the first electrode and the second electrode and overlapped with a portion of the first electrode and a portion of the second electrode. The conductive layer and the electrode layer may overlap each other in an overlapping area in a plane view. The via layer may have a medium thickness, which is equal to or more than 2 μm, in the overlapping area. The separation distance may be equal to or more than 3.0 μm.

### BRIEF DESCRIPTION OF THE DRAWINGS

FIG. 1 is a schematic perspective view illustrating the light-emitting element according to an embodiment.

FIG. 2 is a schematic cross-sectional view illustrating a light-emitting element according to an embodiment.

FIG. 3 is a schematic plan view illustrating a display device according to an embodiment.

FIG. 4 is a schematic cross-sectional view illustrating a display device according to an embodiment.

FIG. 5 is a schematic plan view illustrating a display device according to an embodiment.

FIG. 6 is a schematic cross-sectional view illustrating a display device according to an embodiment.

FIG. 7 shows an experimental example showing a relationship between a medium thickness of a via layer and a separation distance between electrode layers.

FIG. 8 shows schematic cross-sectional views illustrating a relationship between a medium thickness of a via layer and a separation distance between electrode layers.

FIGS. 9 to 12 are schematic cross-sectional views showing each steps of a method of manufacturing a display device according to an embodiment.

FIG. 13 is a block diagram of an electronic device according to an embodiment.

FIG. 14 shows schematic diagrams of electronic devices according to various embodiments.

### DETAILED DESCRIPTION OF THE EMBODIMENTS

Since the present disclosure may be modified in various ways and have multiple forms, specific embodiments will be illustrated and described in detail in the following. However, it should be understood that this is not intended to limit the present disclosure to any specific disclosed forms, and includes all modifications, equivalents, and alternatives that fall within the spirit and the technical scope of the present disclosure.

The terms, “first,” “second,” and the like may be simply used to describe various elements, but those may not be limited to the restricted meanings. The above terms are used only for distinguishing one element from other elements. For example, a first element may be referred to as a second element, and similarly the second element may be referred to as the first constituent element, without departing from the scope of the appended claims. Singular forms are intended to include plural forms unless the context clearly indicates otherwise.

In the specification, the word “comprise” or “has” is used to indicate the existence of a feature, a numbers, a process, an operation, an element, a part, or a combination thereof, and it will be understood that the existence or additional possibility of one or more other features or numbers, processes, operations, elements, parts, or combinations thereof are not excluded in advance. In addition, it will be understood that when an element such as a layer, film, area, or substrate is referred to as being “on” another element, it may be directly on the other element, or intervening elements may also be present therebetween. In addition, in the specification, it will be understood that when an element such as a layer, film, region, or substrate is referred to as being disposed “on” another element, the direction of the arrangement is not limited to an upper direction but also includes the arrangement in a side direction or a lower direction. In contrast, it will be understood that when an element such as a layer, film, area, or substrate is referred to as being “beneath” another element, it may be directly beneath the other element or intervening elements may also be present.

In the present disclosure, compounds described with respect to each of compositions may be synthesized based on generally known processes, and commercially available products may be used in some cases.

In the present disclosure, various physical properties of a target material may be measured at room temperature (20° C.) using general equipment commonly used in the related art, unless otherwise specified.

In the present disclosure, a content (for example, a molar content) of a target material contained in a solid component may be measured in various ways. For example, the content of the target material may be measured or analyzed using a capillary gas chromatograph, a liquid chromatograph, a gel permeation chromatograph, or the like.

The present disclosure relates to a display device, a resin composition, a method of manufacturing the display device, and an electronic device comprising the display device. Hereinafter, a display device, a resin composition, a method of manufacturing the display device, and an electronic device comprising the display device according to an embodiment will be described with reference to the accompanying drawings.

### 1. Resin Composition

A resin composition according to an embodiment will be described.

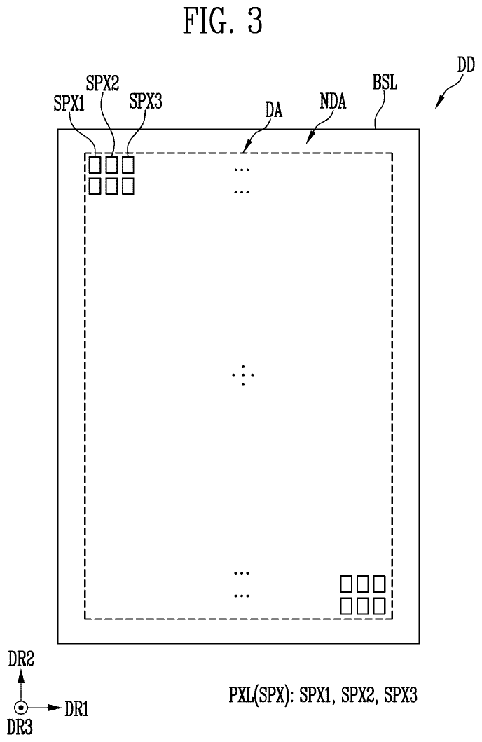

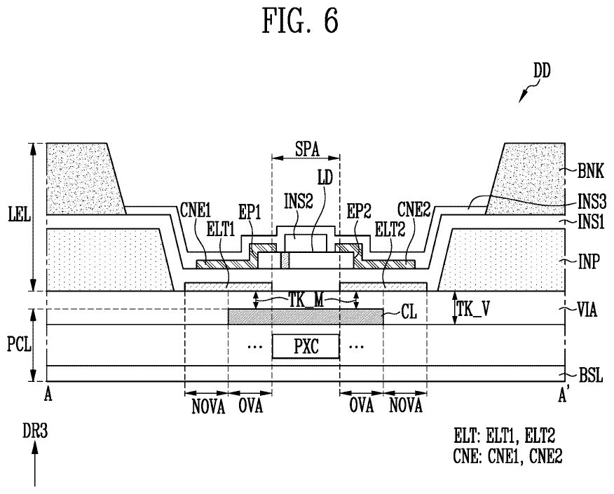

The resin composition according to the embodiment may be used to manufacture a via layer VIA (see FIG. 6) in a display device DD (see FIG. 3). For example, the resin composition may be formed, and a polymerization reaction and a curing reaction with respect to the resin composition may be performed to manufacture the via layer VIA according to an embodiment.

The resin composition may have properties that control the thickness characteristics of the via layer VIA appropriately. For this purpose, the resin composition may include (A) a resin material, (B) a monomer, (C) an initiator, and (D) a solvent.

In the present disclosure, materials included in the resin composition excluding the solvent may be defined as solid components. For example, according to an embodiment, the solid components of the resin composition may include (A) the resin material, (B) the monomer, and (C) the initiator, and the solid components of the resin composition may further include additional material(s).

### (A) Resin Material

The resin material may be the main material of the solid components included in the resin composition according to an embodiment.

The resin material may include an acrylic resin.

The resin material may be included in a relatively high content with respect to the solid components of the resin composition. For example, an amount of the resin material may be in a range from about 3 wt % to about 10 wt % with respect to the entire resin composition.

The resin material may have a relatively large molecular weight. For example, the resin material may have a molecular weight ranging from about 5,000 g/mol to about 15,000 g/mol in average. In this case, the via layer VIA manufactured based on the resin composition may have a relatively low dielectric constant.

The via layer VIA manufactured based on the resin composition according to an embodiment may have a dielectric constant equal to or less than 3.0. The dielectric constant of the via layer VIA manufactured based on the resin composition according to an embodiment may be measured at a room temperature, for example, at 20° C., using equipment known in the art.

Since a content of the resin material satisfies the above-described numerical range and has a relatively large molecular weight within the range described above, structures which form the via layer VIA manufactured based on the resin composition may be suitably stacked. In addition, it is possible to manufacture the via layer VIA having a thickness that is greater than or equal to an intended numerical range. For example, when a polymerization reaction is performed in the resin composition to manufacture the via layer VIA, as a content of a resin material having a relatively high molecular weight is increased, the resin material may be formed more appropriately in a base portion of the via layer VIA, allowing a more effective increase of a thickness of the via layer VIA. That is, according to an embodiment, the content of the resin material is controlled to have a high molecular weight, thereby improving the thickness of the via layer VIA.

### (B) Monomer

The monomer may be served as a target material subject to a polymerization reaction when the polymerization reaction of the resin composition is performed according to an embodiment.

The monomer may include an acrylic monomer.

The monomer may be a multifunctional acrylic monomer. For example, the monomer may include at least one selected from a group consisting of ethoxylated flrorene type diacrylate, phenylthioethyl acrylate, cumyl phonoxy ethyl acrylate, o-phenylphenoxy ethyl acrylate, and m-phonoxy benzyl acrylate.

The monomer may be included in a relatively high content with respect to the solid components of the resin composition. For example, an amount of the monomer may be in a range from about 2 wt % to about 5 wt % relative to the entire resin composition.

When the monomer includes the material(s) described above, and the via layer VIA is manufactured based on the resin composition, structures which form the via layer VIA may be suitably stacked. In addition, it is possible to manufacture the via layer VIA having a thickness that is greater than or equal to an intended numerical range. For example, the monomer may be a target material subject to a polymerization reaction when the via layer VIA is manufactured. As the polymerization reaction with respect to the monomer occurs, materials based on the monomer may be sequentially laminated. In this case, since the monomer may have a relatively bulky structure, the thickness of the via layer VIA may be increased more effectively.

### (C) Initiator

The initiator may be a material which initiates a polymerization reaction of the resin composition according to an embodiment.

The initiator may include a photoinitiator. A content of the initiator in the resin composition may control an extent of the polymerization reaction.

The initiator may include at least one selected from a group consisting of a phosphine oxide compound (for example, IRGACURE 2100 manufactured by Ciba Specialty Chemicals) or phenylbis(2,4,6-trimethylbenzoyl) phosphine oxide) and a metallocene-based compound (for example, IRGACURE 784 manufactured by Ciba Specialty Chemicals).

An amount of the initiator may be in a range from about 1 wt % to about 3 wt % with respect to the entire resin composition. According to an embodiment, the initiator may be contained in a relatively small amount compared to the resin material and the monomer with respect to the entire resin composition. This may be resulted from an increased amount of the resin material and the monomer which have a relatively large molecular weight in order to effectively increase the thickness of the via layer VIA.

In addition, according to an embodiment, in order to manufacture the via layer VIA having an increased thickness, photoinitiation of an acrylic monomer may be performed to cause a rapid increase in molecular weight of a material which forms the via layer VIA. The increase in molecular weight may efficiently increase the thickness of the via layer VIA.

### (D) Solvent

The solvent may include various solvent materials in consideration of the dispersibility of the resin composition and the solubility of materials forming the resin composition.

The solvent may include an organic solvent. For example, the solvent may include at least one selected from a group consisting of methyl 3-methoxypropionate and propylene glycol methyl ether acetate.

The solvent may be contained by a weight ratio excluding the solid components of the resin composition. For example, an amount of the solvent may be in a range from about 82 wt % to about 94 wt % with respect to the entire resin composition.

The resin composition according to an embodiment may further include additives and the like in addition to the materials described above.

For example, the resin composition may include a surfactant as an additive. A surfactant may improve the coating properties of the resin composition and may improve the viscosity of the resin composition. The surfactant may include a silicone-based surfactant. In this case, the surfactant may improve the coating properties such as the dispersibility of the resin composition. As a result, a process of forming the via layer VIA to which the resin composition is applied may be improved.

### 2. Display Device

A display device DD according to an embodiment will be described.

The display device DD according to an embodiment may include a light-emitting element LD.

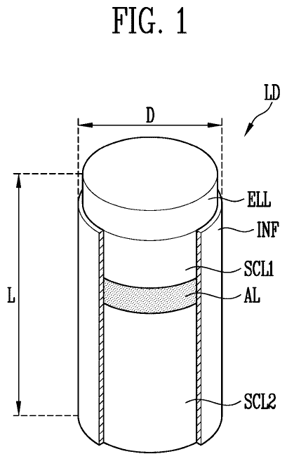

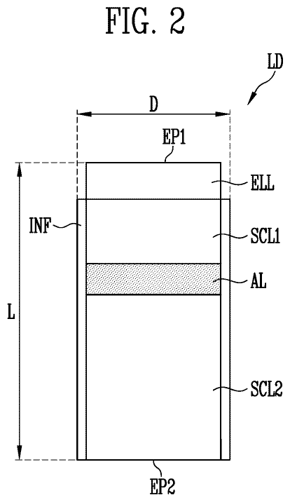

The light-emitting element LD according to an embodiment will be described with reference to FIGS. 1 and 2.

FIG. 1 is a schematic perspective view illustrating the light-emitting element according to an embodiment. FIG. 2 is a schematic cross-sectional view illustrating the light-emitting element according to an embodiment.

The light-emitting element LD is configured to emit light. The light-emitting element LD may include a first semiconductor layer SCL1, a second semiconductor layer SCL2, and an active layer AL disposed between the first semiconductor layer SCL1 and the second semiconductor layer SCL2. According to an embodiment, the first semiconductor layer SCL1, the active layer AL, and the second semiconductor layer SCL2 may be sequentially stacked in a direction of a length L of the light-emitting element LD. According to an embodiment, the light-emitting element LD may further include an electrode layer ELL and an insulating film INF.

The light-emitting element LD may have various shapes. For example, the light-emitting element LD may have a column shape extending in one direction. The column shape may include a rod-like shape or a bar-like shape that is elongated along the direction of the length (for example, with an aspect ratio that is greater than 1), such as a cylindrical column or a polygonal column, and a shape of a cross-section thereof is not particularly limited.

The light-emitting element LD may have a first end portion EP1 and a second end portion EP2. According to an embodiment, the first semiconductor layer SCL1 may be adjacent to the first end portion EP1 of the light-emitting element LD, and the second semiconductor layer SCL2 may be adjacent to the second end portion EP2. According to an embodiment, the first end portion EP1 may be adjacent to the electrode layer ELL.

The light-emitting element LD may be manufactured by etching sequentially stacked semiconductor layers. The light-emitting element LD may have a nano-scale or micro-scale size. For example, a diameter D (or width) of the light-emitting element LD and the length L of the light-emitting element LD may each have a nano-scale or micro-scale. However, the present disclosure is not limited thereto.

The first semiconductor layer SCL1 may include a first conductive type semiconductor. The first semiconductor layer SCL1 may be disposed on the active layer AL and may include a semiconductor layer of a different type from the second semiconductor layer SCL2. For example, the first semiconductor layer SCL1 may include a P-type semiconductor layer. For example, the first semiconductor layer SCL1 may include at least one semiconductor material selected from a group consisting of InAlGaN, GaN, AlGaN, InGaN, AlN, and InN, and may include a P-type semiconductor layer doped with a first conductive dopant such as Ga, B, or Mg. However, the present disclosure is not limited to the example described above. The first semiconductor layer SCL1 may include various materials.

The active layer AL may be disposed between the first semiconductor layer SCL1 and the second semiconductor layer SCL2. The active layer AL may include a single-quantum well or a multi-quantum well structure. The position of the active layer AL is not limited to an example described above and may vary according to a type of the light-emitting element LD.

A clad layer doped with a conductive dopant may be formed on at least one side of the active layer AL. For example, a clad layer doped with a conductive dopant may be formed on either side of the active layer AL, or on both sides of the active layer AL. For example, the clad layer may include at least one selected from a group consisting of AlGaN and InAlGaN. However, the present disclosure is not limited to the example described above.

The second semiconductor layer SCL2 may include a second conductive type semiconductor. The second semiconductor layer SCL2 may be disposed on a second side of the active layer AL, which is opposite to a first side of the active layer AL on which the first semiconductor layer SCL1 is disposed, and may include a semiconductor layer of a different type from the first semiconductor layer SCL1. For example, the second semiconductor layer SCL2 may include an N-type semiconductor layer. For example, the second semiconductor layer SCL2 may include at least one selected from a group consisting of InAlGaN, GaN, AlGaN, InGaN, AlN, and InN, and may include an N-type semiconductor layer doped with a second conductive dopant such as Si, Ge, or Sn. However, the present disclosure is not limited to the example described above. The second semiconductor layer SCL2 may include various materials.

When a voltage that is greater than or equal to a threshold voltage is applied between the first end portion EP1 and the second end portion EP2 of the light-emitting element LD, electron-hole pairs in the active layer AL may recombine with each other, and the light-emitting element LD may emit light. By utilizing this principle to control the emission of light from the light-emitting element LD, the light-emitting element LD may be used as a light source in various devices.

The insulating film INF may be disposed on one surface of the light-emitting element LD. The insulating film INF may surround an outer surface of the active layer AL and may further surround a portion of each of the first semiconductor layer SCL1 and the second semiconductor layer SCL2. The insulating film INF may have a single-layer or multi-layer structure.

The insulating film INF may not cover the first end portion EP1 and the second end portion EP2 of the light-emitting element LD which have different polarities. For example, the insulating film INF may not cover portions of the first end portion EP1, the electrode layer ELL adjacent to the first semiconductor layer SCL1 and the second end portion EP2 of the light-emitting element LD. The insulating film INF may secure the electrical stability of the light-emitting element LD. In addition, the insulating film INF may minimize surface defects of the light-emitting element LD and improve a lifespan and efficiency of the light-emitting element LD. In addition, when a plurality of light-emitting elements LD are disposed in close contact with each other, the insulating film INF may prevent short-circuit defects between the light-emitting elements LD.

According to an embodiment, the insulating film INF may include at least one selected from a group consisting of silicon oxide (SiOₓ), silicon nitride (SiNₓ), silicon oxynitride (SiOₓN_{y}), aluminum oxide (AlₓO_{y}), and titanium oxide (TiOₓ). However, the present disclosure is not limited to the example described above.

The electrode layer ELL may be disposed on the first semiconductor layer SCL1. The electrode layer ELL may be adjacent to the first end portion EP1. The electrode layer ELL may be electrically connected to the first semiconductor layer SCL1. A portion of the electrode layer ELL may be not covered by the insulating film INF. For example, the insulating film INF may not cover a portion of the electrode layer ELL corresponding to the first end portion EP1. For example, the insulating film INF may not cover a side surface of the electrode layer ELL. For example, the insulating film INF may cover each of a side surface of each of the first semiconductor layer SCL1, the active layer AL, and the second semiconductor layer SCL2 and may not cover at least a portion of the side surface of the electrode layer ELL. When at least a portion of the side surface of the electrode layer ELL is not covered by the insulating film INF, electrical connection to other components from the electrode layer ELL adjacent to the first end portion EP1 may be facilitated. According to an embodiment, the insulating film INF may not cover not only the side surface of the electrode layer ELL, but also a portion of the side surface of at least one of the first semiconductor layer SCL1 or the second semiconductor layer SCL2.

According to an embodiment, the electrode layer ELL may be an Ohmic contact electrode. However, the present disclosure is not limited to the example described above. For example, the electrode layer ELL may be a schottky contact electrode.

According to an embodiment, the electrode layer ELL may include at least one selected from a group consisting of chromium (Cr), titanium (Ti), aluminum (Al), gold (Au), nickel (Ni), an oxide thereof, and an alloy thereof. However, the present disclosure is not limited to the example described above. According to an embodiment, the electrode layer ELL may be substantially transparent. For example, the electrode layer ELL may include indium tin oxide (ITO). Accordingly, the electrode layer ELL may transmit emitted light.

The structure and shape of the light-emitting element LD are not limited to the example described above, and the light-emitting element LD may have various structures and shapes according to an embodiment. For example, the light-emitting element LD may further include an additional electrode layer which is disposed on one surface of the second semiconductor layer SCL2 and is adjacent to the second end portion EP2.

FIG. 3 is a schematic plan view illustrating a display device according to an embodiment.

Referring to FIG. 3, a display device DD may include a base layer BSL and pixels PXL disposed on the base layer BSL. Each of the pixels PXL may include light-emitting elements LD. The display device DD may further include a driving circuit unit (for example, a scan driver and a data driver) for driving the pixels PXL, signal lines and pads.

The display device DD (or the base layer BSL) may include a display area DA and a non-display area NDA. The non-display area NDA may refer to an area other than the display area DA. The non-display area NDA may surround at least a portion of the display area DA.

The base layer BSL may form a base surface of the display device DD. According to an embodiment, the base layer BSL may be a lower substrate for arranging layers which form the display device DD. The base layer BSL may be a rigid or flexible substrate or film. For example, the base layer BSL may include a glass material. For example, the base layer BSL may include a silicon material. For example, the base layer BSL may include polyimide. However, the present disclosure is not limited thereto.

A plane defined in the present disclosure may extend in a first direction DR1 and a second direction DR2 which is cross the first direction DR1 in the plane. According to an embodiment, a third direction DR3 may be a thickness direction of the base layer BSL, and the third direction DR3 may be a direction in which the display device DD emits light.

The display area DA may refer to an area in which the pixel PXL is disposed. The non-display area NDA may refer to an area in which the pixel PXL is not disposed. The driving circuit unit, the signal lines, and the pads connected to the pixel PXL of the display area DA may be disposed in the non-display area NDA.

According to an embodiment, the pixels PXL (or sub-pixels SPX) may be arranged according to a stripe or PenTile™ array structure, but the present disclosure is not limited thereto. Various embodiments may be applied to the disclosure.

According to an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form one pixel unit capable of emitting light having various colors.

Each of the first sub-pixel SPX1, the second sub-pixel SPX2, and the third sub-pixel SPX3 may emit light having a different color than others.

For example, the first sub-pixel SPX1 may be a red pixel that emits light having a red color (for example, a first color), the second sub-pixel SPX2 may be a green pixel that emits light having a green color (for example, a second color), and the third sub-pixel SPX3 may be a blue pixel that emits light having a blue color (for example, a third color). The red pixel may provide light with a wavelength band of 600 nm to 750 nm. The green pixel may provide light with a wavelength band of 480 nm to 560 nm. The blue pixel may provide light with a wavelength band of 370 nm to 460 nm.

According to an embodiment, the number of second sub-pixels SPX2 may be greater than each of the number of first sub-pixel SPX1 and the number of third sub-pixels SX3. However, the colors, types, or numbers of the first sub-pixel SPX1, the second sub-pixel SPX2, and the third sub-pixel SPX3 forming each pixel unit are not limited to the examples described above.

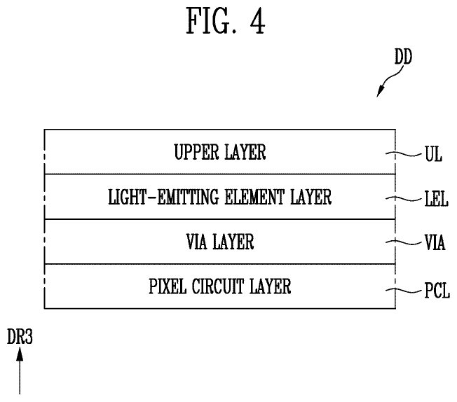

FIG. 4 is a schematic cross-sectional view illustrating a display device according to an embodiment.

Referring to FIG. 4, a display device DD may include a pixel circuit layer PCL, a via layer VIA, a light-emitting element layer LEL, and an upper layer UL.

The pixel circuit layer PCL may include a base layer BSL. The pixel circuit layer PCL may be a layer including a pixel circuit PXC (see FIG. 6). The pixel circuit layer PCL may be a backplane layer. The pixel circuit PXC may be formed on the base layer BSL and may be configured to drive a light-emitting element LD. The pixel circuit layer PCL may include conductive layers and insulating layers, and the conductive layers may form the pixel circuit PXC. The pixel circuit PXC may include circuit elements. The circuit elements may include a driving transistor and may also include additional transistors and capacitors.

A via layer VIA may be disposed on a pixel circuit layer PCL. The via layer VIA may cover the pixel circuit PXC.

The light-emitting element layer LEL may be disposed on the via layer VIA. The light-emitting element layer LEL may be a layer including the light-emitting element LD.

The upper layer UL may be disposed on the light-emitting element layer LEL. The upper layer UL may include various layer(s), which transmit light, such as a cover window. According to an embodiment, the upper layer UL may include a color filter, a range array layer, or a polarizing layer. According to an embodiment, the upper layer UL may include a color conversion layer including light conversion particles (for example, quantum dots) that convert a wavelength of applied light. However, the present disclosure is not limited to an example described above.

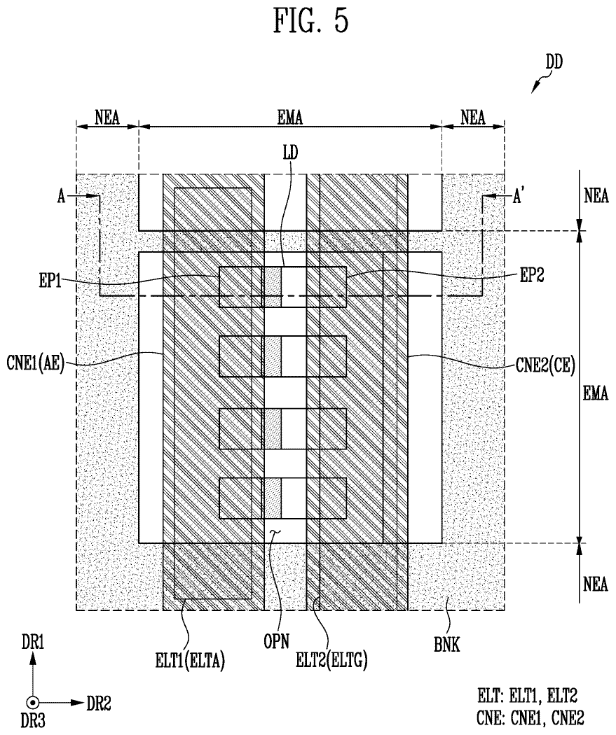

A display device DD including a via layer VIA based on a resin composition according to an embodiment will be described with reference to FIGS. 5 to 8.

FIG. 5 is a schematic plan view illustrating the display device according to an embodiment. FIG. 6 is a schematic cross-sectional view illustrating the display device according to an embodiment. More specifically, FIG. 6 is a schematic cross-sectional view taken along a line AA′ of FIG. 5.

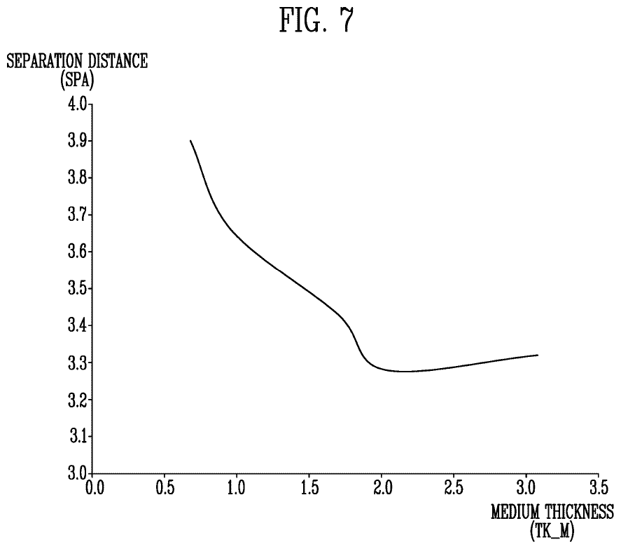

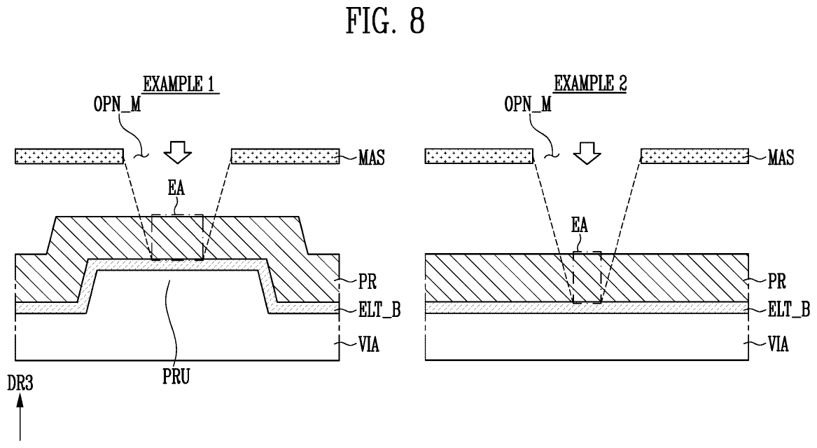

FIG. 7 shows an experimental example showing a relationship between a medium thickness of the via layer and a separation distance between electrode layers. FIG. 8 shows schematic cross-sectional views illustrating the relationship between the medium thickness of the via layer and the separation distance between the electrode layers.

Referring to FIGS. 5 to 8, the display device DD may include an emission area EMA and a non-emission area NEA. The display device DD may include a bank BNK, an electrode layer ELT, light-emitting elements LD, and a connection electrode layer CNE.

The emission area EMA may overlap an opening OPN, which is defined by the bank BNK, in a plane view. The light-emitting elements LD may be disposed in the emission area EMA. The light-emitting elements LD may not be disposed in the non-emission area NEA.

A bank BNK may form (or provide) an opening OPN. For example, the bank BNK may have a shape that protrudes in a thickness direction of a base layer BSL (for example the third direction DR3) and may surround one area. According to an embodiment, ink including the light-emitting element LD may be supplied to the opening OPN defined by a bank BNK so that the light-emitting element LD may be disposed in the opening OPN.

According to an embodiment, the bank BNK may include an organic material such as an acrylic resin, an epoxy resin, a phenol resin, a polyamide resin, a polyimide resin, a polyester resin, a polyphenylenesulfide resin, or benzocyclobutene (BCB). However, the present disclosure is not limited to the examples described above.

The electrode layer ELT may include electrodes for aligning the light-emitting elements LD. The electrode layer ELT may be referred to as an alignment electrode layer. According to an embodiment, the electrode layer

ELT may include a first electrode ELT1 and a second electrode ELT2. According to an embodiment, the first electrode ELT1 may be a first alignment electrode ELTA, and the second electrode ELT) may be a second alignment electrode ELTG.

The light-emitting element LD may be disposed (or aligned) on the electrode layer ELT. According to an embodiment, the light-emitting element LD may be aligned between the first electrode ELT1 and the second electrode ELT2 in a plane view. The light-emitting elements LD may form (or constitute) an emission unit.

According to an embodiment, the first electrode ELT1 and the second electrode ELT2 may be spaced apart from each other along the second direction DR2 in light emission area EMA. The first electrode ELT1 and the second electrode ELT2 may extend in the first direction DR1.

According to an embodiment, the first and second electrodes ELT1 and ELT2 may include various conductive materials. For example, a conductive layer CL may include at least one selected from a group consisting of gold (Au), silver (Ag), tantalum (Ta), aluminum (AI), molybdenum (Mo), chromium (Cr), titanium (Ti), nickel (Ni), neodymium (Nd), copper (Cu), and platinum (Pt). However, the disclosure is not limited thereto.

According to an embodiment, the first electrode ELT1, which is the first alignment electrode ELTA, may be an electrode to which an AC signal may be supplied to align the light-emitting elements LD. The first electrode ELT1 may be an electrode to which an anode signal may be supplied such that the light-emitting elements LD emit light. The second electrode ELT2, which is the second alignment electrode ELTG, may be an electrode to which a ground signal may be supplied to align the light-emitting elements LD. The second electrode ELT2 may be an electrode to which a cathode signal may be supplied so that the light-emitting element LD emit light.

The first electrode ELT1 (or the first alignment electrode ELTA) and the second electrode ELT2 (or the second alignment electrode ELTG) may receive a first alignment signal and a second alignment signal, respectively, in a process step in which the light-emitting elements LD are aligned. For example, when ink INK including a light-emitting element LD may be supplied to the opening OPN, the first alignment signal and the second alignment signal may be supplied to the first electrode ELT1, and the second electrode ELT2, respectively. In this case, the first alignment signal and the second alignment signal may have different waveforms, potentials, or phases. For example, the first alignment signal may be an AC signal, and the second alignment signal may be a ground signal. However, the present disclosure is not limited to an example described above. An electric field may be formed between (or on) the first electrode ELT1 and the second electrode ELT2 to align the light-emitting elements LDs between the first electrode ELT1 and the second electrode ELT2 based on the electric field. For example, the light-emitting elements LDs may be moved (or rotated) by a force (for example, a dielectrophoresis (DEP) force) according to the electric field and aligned (or disposed) on the first alignment electrode ELTA and the second alignment electrode ELTG.

The light-emitting element LD may emit light based on a provided electrical signal. For example, the light-emitting element LD may provide light based on a first electrical signal (for example, an anode signal) provided from a first connection electrode CNE1 and a second electrical signal (for example, a cathode signal) provided from a second connection electrode CNE2.

A first end portion EP1 of the light-emitting element LD may be positioned adjacent to the first electrode ELT1, and a second end portion EP2 of the light-emitting element LD may be positioned adjacent to the second electrode ELT2.

The light-emitting element LD may be disposed in the opening OPN. The light-emitting element LD may form an emission region. The emission area EMA may include an area in which the light-emitting element LD is disposed.

The connection electrode layer CNE may be disposed on the first end portions EP1 and the second end portions EP2 of the light-emitting elements LD. The first connection electrode CNE1 may be disposed on the first end portions EP1 to be electrically connected to the first end portions EP1 of the light-emitting elements LD. The second connection electrode CNE2 may be disposed on the second end portions EP2 to be electrically connected to the second end portions EP2 of the light-emitting elements LD.

According to an embodiment, the connection electrode layer CNE may include the first connection electrode CNE1 and the second connection electrode CNE2. The first connection electrode CNE1 may be an anode connection electrode AE, and the second connection electrode CNE2 may be a cathode connection electrode CE. According to an embodiment, the first connection electrode CNE1 may electrically connect the first electrode ELT1 to the first end portion EP1 of the light-emitting elements LD. The second connection electrode CNE2 may electrically connect the second electrode ELT2 to the second portion EP2 of the light-emitting elements LD.

The pixel circuit layer PCL may include the base layer BSL and a pixel circuit PXC patterned on the base layer BSL.

The pixel circuit layer PCL may further include the conductive layer CL.

The conductive layer CL may be a layer formed at an uppermost side among conductive layers of the pixel circuit layer PCL. For example, the conductive layer CL may be the closest to the light-emitting element LD among the conductive layers of the pixel circuit layer PCL.

According to an embodiment, the conductive layer CL may be electrically connected to the pixel circuit PXC. Although not shown in the drawing, according to an embodiment, the conductive layer CL may be electrically connected to the first electrode ELT1 through a contact hole (which is not shown) extending through the via layer VIA or the first connection electrode CNE1 through a contact hole (which is not shown) extending through the via layer VIA and a first insulating layer INS1.

The conductive layer CL may include various conductive materials. For example, the conductive layer CL may include at least one selected from a group consisting of gold (Au), silver (Ag), tantalum (Ta), aluminum (Al), molybdenum (Mo), chromium (Cr), titanium (Ti), nickel (Ni), neodymium (Nd), copper (Cu), and platinum (Pt). However, the present disclosure is not limited thereto.

The conductive layer CL may overlap the light-emitting element LD in a plane view. The conductive layer CL may overlap an area between the first electrode ELT1 and the second electrode ELT2 in a plane view. According to an embodiment, the conductive layer CL may overlap the electrode layer ELT in a plane view.

The via layer VIA may be disposed on the pixel circuit layer PCL. The via layer VIA may cover the conductive layer CL. For example, the via layer VIA may entirely cover an upper surface of the conductive layer CL. The via layer VIA may be in contact with the conductive layer CL. For example, the via layer VIA may be directly adjacent to the upper surface of the conductive layer CL.

The via layer VIA may be manufactured using a resin composition according to an embodiment. For example, a layer including the resin composition according to an embodiment may be deposited to cover the conductive layer CL, and a polymerization reaction and a curing reaction of the deposited resin composition may be performed to manufacture the via layer VIA according to an embodiment.

Although not shown in the drawing, a contact portion that electrically connects the pixel circuit PXC and the electrode layer ELT may be formed in a portion of the via layer VIA.

The via layer VIA may have a medium thickness TK_M in an overlapping area OVA in which the conductive layer CL and the electrode layer ELT overlap each other in a plane view.

The via layer VIA may have a via thickness TK_V in a non-overlapping area NOVA in which the conductive layer CL and the electrode layer ELT do not overlap each other in a plane view. According to an embodiment, in the non-overlapping area NOVA, the conductive layer CL may not be disposed, but the electrode layer ELT may be disposed.

The via thickness TK_V may be greater than the medium thickness TK_M. For example, the via layer VIA may be formed to have a sufficient overall thickness so that the via layer VIA may suitably planarize a stepped portion formed by the conductive layer CL or the like.

Accordingly, an upper surface of the via layer VIA may include a substantially flat surface. For example, the via layer VIA may include a flat surface formed in the overlapping area OVA and the non-overlapping area NOVA.

According to an embodiment, the medium thickness TK_M may be in a range of 2 μm to 5 μm. According to an embodiment, the medium thickness TK_M may be in a range of 2 μm to 4 μm.

When the medium thickness TK_M satisfies the above-described numerical range, the first and second electrodes ELT1 and ELT2 may be patterned relatively adjacent to each other, and the alignment of the light-emitting elements LD may be improved between the first electrode ELT1 and the second electrode ELT2.

Accordingly, light-emitting elements LD may be closely disposed in a relatively narrow area, and the display device DD may provide excellent display quality such as high resolution characteristics.

A relationship between the medium thickness TK_M and a separation distance SPA between the first electrode ELT1 and the second electrode ELT2 will be described with reference to FIGS. 7 and 8.

Referring to FIG. 7, under a same process conditions, when the medium thickness TK_M is changed, the separation distance SPA between the first electrode ELT1 and the second electrode ELT2 may be changed.

For example, the separation distance SPA according to the medium thickness TK_M was measured under a same process condition, a same material of the electrode layer ELT was used in each experiment, a same material of the via layer VIA was used, and a same process environment was applied.

According to an embodiment, when the medium thickness TK_M is less than 2 μm, the separation distance SPA may decrease as the medium thickness TK_M increases. Additionally, when the medium thickness TK_M is greater than 2 μm, the separation distance SPA may increase as the medium thickness TK_M increases.

That is, as the medium thickness TK_M increases, the separation distance SPA may tend to decrease as long as the medium thickness TK_M is 2 μm or less.

Theoretically, the display device DD may provide high resolution characteristics when the first and second electrodes ELT1 and ELT2 are closely spaced from each other in a same area. That is, the medium thickness TK_M according to an embodiment may be 2 μm or more, and thus the display device DD according to an embodiment may be designed to the medium thickness TK_M having a sufficient thickness while the separation distance SPA between the first electrode ELT1 and the second electrode ELT2 is sufficiently short.

In addition, according to an embodiment, when the medium thickness TK_M is greater than 5 μm, outgassing in the pixel circuit layer PCL may not occur smoothly. Accordingly, according to an embodiment, when the medium thickness TK_M satisfies the above-described numerical range, an outgassing path may be certainly secured and structural stability in the pixel circuit layer PCL may be obtained.

The tendency of the separation distance SPA depending on a degree to which the via layer VIA planarizes a lower portion of the electrode layer ELT will be described with reference to FIG. 8.

In FIG. 8, a first example EXAMPLE 1 shows a structure in which the via layer VIA does not adequately planarize a stepped portion formed by components below the via layer VIA. In FIG. 8, a second example EXAMPLE 2 shows a structure in which a via layer VIA adequately planarizes a stepped portion formed by the components below the via layer VIA. In FIG. 8, the via layer VIA was manufactured using a resin composition according to an embodiment.

The first and second examples show a process step in which a base electrode layer ELT_B is formed (for example, deposited) on the via layer VIA to pattern the first and second electrodes ELT1 and ELT2, and a photoresist PR is formed on the base electrode layer ELT_B. After the base electrode layer ELT_B and the photoresist PR are deposited on the via layer VIA, an exposure step is performed using a mask MAS including a mask opening OPN_M.

Referring to the first example, since the via layer VIA does not suitably planarize lower stepped portions, a protrusion PRU is formed. Since the protrusion PRU is formed, portions of the base electrode layer ELT_B and the photoresist PR are formed at a relatively high level by the protrusion PRU. Thus, during an exposure step using the mask MAS, applied light is provided to a partial area EA of the photoresist PR.

In contrast, as the via layer VIA in the second example suitably planarizes the lower stepped portions, the protrusion PRU is not formed. Since the protrusion PRU is not formed in the second example, the base electrode layer ELT_B and the photoresist PR are formed at relatively a same level for each area of the via layer VIA. Accordingly, during an exposure step using the mask MAS, applied light is provided to the partial area EA of the photoresist PR.

Referring to the first and second examples, it may be seen that the area EA of the photoresist PR to which light is applied in the first example is formed at a higher level than the area EA of the photoresist PR to which light is applied in the second example. In the first and second examples, since other process factors such as a height of the mask MAS and a size of the mask opening OPN_M are set to be the same, when a height of the area EA increases, an incident angle through the mask opening OPN_M may be reduced, and the exposed area EA may be widened.

That is, the exposed area EA in the second example may be narrower as compared to the first example. As the base electrode layer ELT may be etched using an etching mask which is a remaining portion of the photoresist PR after removing the exposed area EA, the separation distance SPA between the first electrode ELT1 and the second electrode ELT2 is determined by the width of the etching mask. As a result, in the second example, as compared to the first example, the first and second electrodes ELT1 and ELT2 in the second example may have a shorter separation distance than the first example.

Accordingly, it may be understood that as the medium thickness TK_M of the via layer VIA increases to reach 2 μm, the via layer VIA becomes more flattened, and the separation distance SPA becomes shorter. According to an embodiment, it may be understood that, through a fact that, until the medium thickness TK_M of the via layer VIA becomes 2 μm, the separation distance SPA decreases as the medium thickness TK_M of the via layer VIA increases. And after the medium thickness TK_M of the via layer VIA exceeds 2 μm or more, the via layer VIA suitably planarizes the stepped portions by the lower components such as the conductive layer CL.

Accordingly, according to an embodiment, the medium thickness TK_M of the via layer VIA is controlled within a predetermined numerical range, thereby reducing an amount of material used in manufacturing the via layer VIA.

Meanwhile, according to an embodiment, as described above, when the via layer VIA has a medium thickness TK_M of 2 μm or more, the alignment of the light-emitting elements LD may be improved.

For example, the conductive layer CL covered by the via layer VIA may be disposed below the light-emitting element LD. According to an embodiment, since conductive structures included in the pixel circuit layer PCL may be disposed below the light-emitting element LD, the conductive structures may be closely patterned in a narrow area, thereby providing the display device DD with high resolution characteristics.

However, experimentally, since the conductive structures (for example, the conductive layers CL) included in the pixel circuit layer PCL are positioned below the light-emitting element LD, there may be a risk of a distortion of an alignment signal during an alignment process of aligning the light-emitting elements LD due to an electric field formed between the first electrode ELT1 and the second electrode ELT2. For example, there may be a risk that an alignment signal is partially distorted due to the a capacitance generated between the conductive layer CL and the electrode layer ELT. As a result, differences in aligning the light-emitting elements LD between sub-pixels may be caused. In this case, there may be a risk that display quality may be deteriorated due to the differences in luminance between sub-pixels SPX.

According to an embodiment, even when the conductive layer CL is disposed below the light-emitting element LD, since the via layer VIA has a thickness of 2 μm or more in the overlapping area OVA, distortion of an alignment signal by the conductive layer CL during an alignment process of the light-emitting element LD may be prevented, and as a result, the display device DD with improved display quality may be provided.

In addition, the technical feature of having the medium thickness TK_M of 2 μm or more may help not only prevention of the distortion of the alignment signal as described above but also relate to a critical value for the tendency of the separation distance SPA with respect to the medium thickness TK_M.

Since the via layer VIA according to an embodiment is formed using the resin composition according to the embodiment, as discussed above, the medium thickness TK_M in the overlapping area OVA may have a sufficient thickness which is 2 μm or more.

That is, according to an embodiment, by using a resin composition capable of adequately improving the thickness of the via layer VIA, the via layer VIA may be manufactured such that the medium thickness TK_M has an appropriate numerical range, thereby manufacturing the display device DD having excellent display quality and high resolution characteristics.

Referring back to FIG. 6, a light-emitting element layer LEL according to an embodiment may include an insulating pattern layer INP, the electrode layer ELT, a first insulating layer INS1, the bank BNK, the light-emitting element LD, a second insulating layer INS2, the connection electrode layer CNE, and a third insulating layer INS3.

An insulating pattern layer INP may be disposed on the via layer VIA. The insulating pattern layer INP may include first insulating pattern portions and second insulating pattern portions that are spaced apart from each other. The insulating pattern layer INP may have various shapes according to an embodiment. In an embodiment, the insulating pattern layer INP may protrude in a thickness direction (for example, in a third direction DR3 with respect to a display base layer DBSL).

The insulating pattern layer INP may form a stepped portion such that the light-emitting elements LDs may be easily positioned in the emission area EMA. According to an embodiment, the insulating pattern layer INP may be a partition wall. According to an embodiment, the insulating pattern layer INP may include at least one organic material or inorganic material. However, the present disclosure is not limited to an example above.

The first and second electrodes ELT1 and ELT2 may be disposed on the via layer VIA and the insulating pattern layer INP. The first electrode ELT1 may receive a first alignment signal or a first power through a first power line PL1. The second electrode ELT2 may receive a second alignment signal or a second power through a second power line PL2.

According to an embodiment, the first electrode ELT1 and the second electrode ELT2 may be spaced apart by the separation distance SPA. According to an embodiment, the separation distance SPA may be defined based on a direction in which the first electrode ELT1 and the second electrode ELT2 are spaced from each other (for example, in a second direction DR2).

According to an embodiment, the separation distance SPA may be 3.0 μm or more. The separation distance SPA may be equal to or less than 3.5 μm. According to an embodiment, the separation distance SPA may be in a range of 3.0 μm to 3.5 μm. According to an embodiment, the separation distance SPA may be in a range of 3.2 μm and 3.5 μm. According to an embodiment, when the via layer VIA has a predetermined thickness as described above, the separation distance SPA may have the abode-described numerical range. That is, when the separation distance SPA satisfies the above-described numerical range, it is possible to provide a technical feature according to an embodiment that arise from having the medium thickness TK_M of 2 μm or more in the via layer VIA.

The first insulating layer INS1 may be disposed on the first and second electrodes ELT1 and ELT2 and the insulating pattern layer INP. The first insulating layer INS1 may include an inorganic material. For example, the first insulating layer INS1 may include at least one selected from a group consisting of silicon oxide (SiOₓ), silicon nitride (SiNₓ), silicon oxynitride (SiOₓN_{y}), aluminum oxide (AlₓO_{y}), and titanium oxide (TiOₓ). However, the present disclosure is not limited to the examples described above.

The bank BNK may be disposed on the first insulating layer INS1. As described above, the bank BNK may form a space in which ink including the light-emitting element LD may be accommodated.

The light-emitting element LD may be disposed (for example, directly disposed) on the first insulating layer INS1 in an area surrounded by the bank BNK. According to an embodiment, the light-emitting element LD may emit light based on electrical signals (for example, an anode signal and a cathode signal) provided from the first connection electrode CNE1 and the second connection electrode CNE2.

The second insulating layer INS2 may be disposed on the light-emitting element LD. The second insulating layer INS2 may cover an active layer AL of the light-emitting element LD. The second insulating layer INS2 may expose at least a portion of the light-emitting element LD. For example, the second insulating layer INS2 may not cover the first end portion EP1 and the second end portion EP2 of the light-emitting element LD, and thus the first end portion EP1 and the second end portion EP2 of the light-emitting element LD may be electrically connected to the first connection electrode CNE1 and the second connection electrode CNE2, respectively. According to an embodiment, another portion of the second insulating layer INS2, where the light-emitting element LD is not placed, may be disposed on the bank BNK and the first insulating layer INS1.

When the second insulating layer INS2 is formed on the light-emitting elements LD after the alignment of the light-emitting elements LD is completed, the light-emitting elements LD may be prevented from shifting from the alignment positions of the light-emitting elements LD.

The second insulating layer INS2 may have a single layer or multilayer structure. The second insulating layer INS2 may include at least one selected from a group consisting of silicon oxide (SiOₓ), silicon nitride (SiNₓ), silicon oxynitride (SiOₓN_{y}), aluminum nitride (AlNₓ), aluminum oxide (AlₓO_{y}), zirconium oxide (ZrOₓ), hafnium oxide (HfOₓ), and titanium oxide (TiOₓ). However, the present disclosure is not limited to the examples described above.

The first connection electrode CNE1 and the second connection electrode CNE2 may be disposed on the first insulating layer INS1 and the light-emitting element LD. The first connection electrode CNE1 may be electrically connected to the first end portion EP1 of the light-emitting element LD. The second connection electrode CNE2 may be electrically connected to the second end portion EP2 of the light-emitting element LD.

The first connection electrode CNE1 may be electrically connected to the first electrode ELT1 through a first contact hole (which is not shown) extending through the first insulating layer INS1, and the second connection electrode CNE2 may be electrically connected to the second electrode ELT2 through a second contact hole (which is not shown) extending through the first insulating layer INS1. According to an embodiment, the first connection electrode CNE1 may be electrically connected to the pixel circuit PXC without passing through the first electrode ELT1. The second connection electrode CNE2 may also be electrically connected to the second power line PL2 without going through the second electrode ELT2.

According to an embodiment, the first connection electrode CNE1 and the second connection electrode CNE2 may be patterned at the same time in the same process. However, the present disclosure is not limited to an example described above. After any one of the first connection electrode CNE1 or the second connection electrode CNE2 is patterned, the remaining electrode may be patterned.

The third insulating layer INS3 may be disposed on the first insulating layer INS1, the second insulating layer INS2, and the first and second connection electrodes CEN1 and CNE2. The third insulating layer INS3 may include an inorganic material. For example, the third insulating layer INS3 may include at least one selected from a group consisting of silicon oxide (SiOₓ), silicon nitride (SiNₓ), silicon oxynitride (SiOₓN_{y}), aluminum oxide (AlₓO_{y}), and titanium oxide (TiOₓ). However, the present disclosure is not limited to the examples described above.

### 3. Method of Manufacturing Display Device

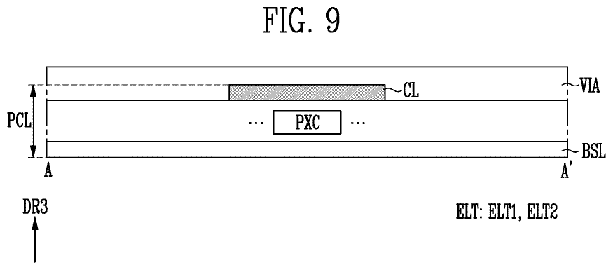

A method of manufacturing a display device DD according to an embodiment will be described with reference to FIGS. 9 to 12. Explanations that already made above will be briefly described or omitted.

FIGS. 9 to 12 are schematic cross-sectional views showing each steps of the method of manufacturing a display device according to an embodiment. For convenience of description, FIGS. 9 to 12 are illustrated based on the cross-sectional structure described above with reference to FIG. 6.

Referring to FIG. 9, a pixel circuit PXC may be patterned on a base layer BSL, and a conductive layer CL may be patterned on the pixel circuit PXC. A via layer VIA covering the conductive layer CL may be disposed.

According to an embodiment, a conductive layer or an insulating layer on the base layer BSL may be formed through a typical processes in manufacturing a semiconductor device. For example, the conductive layer or the insulating layer on the base layer BSL may be formed through a photolithography process, etched through various methods (wet etching, dry etching, and the like), and deposited through various methods (sputtering, chemical vapor deposition, and the like). The present disclosure is not necessarily limited to the examples described above.

The via layer VIA may be formed using a resin composition according to an embodiment. A base via layer including the resin composition according to an embodiment may be disposed or deposited to cover the conductive layer CL, and light may be applied onto the base via layer to cause a polymerization reaction and a curing reaction, thereby forming the via layer VIA according to an embodiment.

A method of depositing the base via layer including the resin composition is not particularly limited. For example, the base via layer including the resin composition may be deposited through a spin coating process or the like. However, the present disclosure is not limited thereto.

According to an embodiment, as described above, since the resin composition includes a resin material and a monomer having a relatively high molecular weight and bulky structural characteristics, the formed via layer VIA may have a thickness that is greater than or equal to a predetermined numerical range.

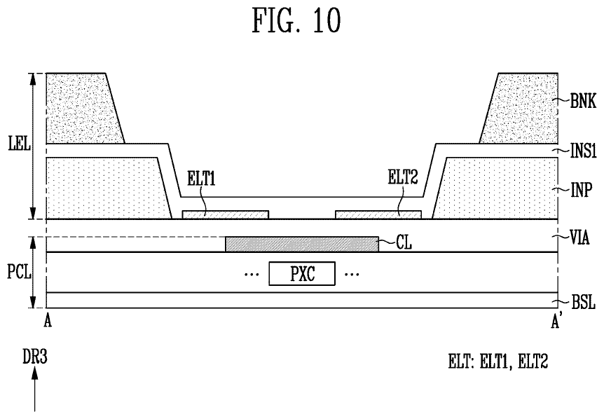

Referring to FIG. 10, some components of a light-emitting element layer LEL may be patterned on the via layer VIA.

For example, insulating pattern layers INP and an electrode layer ELT may be patterned on the via layer VIA, a first insulating layer INS1 covering the insulating pattern layer INP and the electrode layer ELT may be formed, and the bank BNK may be patterned on the first insulating layer INS1. Through this step, first and second electrodes ELT1 and ELT2 spaced apart from each other may be patterned, and the bank BNK surrounding one area may be patterned.

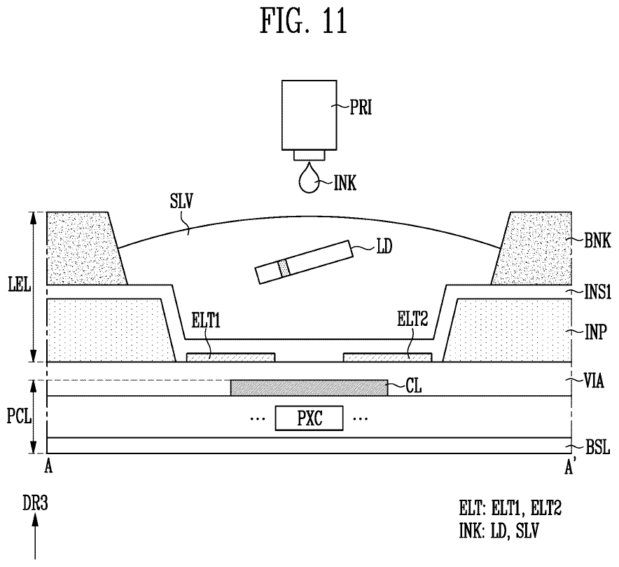

Referring to FIG. 11, a printing device PRI may supply ink INK) including light-emitting elements LD and a solvent SLV onto a pixel circuit layer PCL (for example, the base layer BSL). For example, the printing device PRI may supply ink including the light-emitting elements LD and the solvent SLC into an area surrounded by the bank BNK.

The solvent SLV may include an organic solvent. For example, the solvent SLV may be one selected from a group consisting of propylene glycol methyl ether acetate (PGMEA), dipropylen glycol n-propyl ether (DGPE), and triethylene gylcol n-butyl ether (TGBE). However, the present disclosure is not limited to the examples described above.

The printing device PRI may be configured to eject a fluid. For example, the printing device PRI may include a nozzle unit.

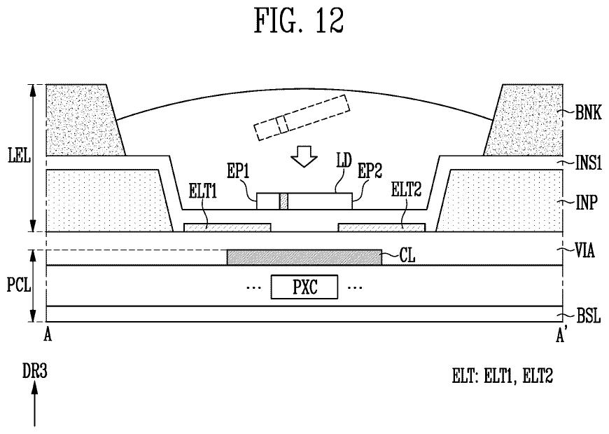

Referring to FIG. 12, an alignment signal may be supplied to the first electrode ELT1 and the second electrode ELT2, and the light-emitting elements LD may be aligned based on an electric field generated the alignment signal between the first electrode ELT1 and the second electrode ELT2.

For example, a first alignment signal may be supplied to the first electrode ELT1, and a second alignment signal may be supplied to the second electrode ELT2. Based on an electric field generated according to the first alignment signal and the second alignment signal, the light-emitting elements LD may be aligned between the first electrode ELT1 and the second electrode ELT2.

According to an embodiment, the first and second electrodes ELT1 and ELT2 may be spaced apart from each other by a relatively narrow separation distance SPA so that the light-emitting elements LD may be closely aligned in a relatively narrow area. In addition, since the via layer VIA separates the conductive layer CL and the electrode layer ELT from each other by a sufficient thickness, it is possible to reduce a risk of unintended capacitance being generated between the conductive layer CL and the electrode layer ELT when an alignment process is performed.

Next, according to an embodiment, the solvent SLV may be removed, and the second electrode ELT2, a connection electrode layer CNE, and an upper layer UL may be disposed, thereby providing a display device DD.

The display device DD according to embodiments may be applied to various electronic devices. The electronic device 10 according to an embodiment includes the above-described display device DD and may further include other modules or devices with additional functions besides the display device DD.

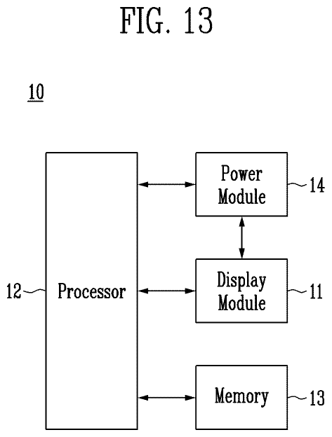

FIG. 13 is a block diagram of an electronic device according to an embodiment. Referring to FIG. 13, the electronic device 10 according to an embodiment may include a display module 11, a processor 12, memory 13, and a power module 14.

The processor 12 may include at least one of a central processing unit CPU, an application processor (AP), a graphic processing unit (GPU), a communication processor (CP), an image signal processor (ISP), and a controller.

The memory 15 may store data information needed for the operation of the processor 12 or the display module 11. When the processor 12 executes an application stored in memory 15, video data signals and/or input control signals are delivered to the display module 11 (e.g., display device DD), and the display module 11 processes the received signals to output image information through the display screen.

The power module 14 may include a power supply module, such as a power adapter or a battery device, and a power conversion module that converts the power supplied by the power supply module to generate the power needed for the operation of the electronic device 10. The power module 14 may be configured to supply power to the display module 11 (e.g., display device DD).

At least one of each component of the aforementioned electronic device 11 may be included in the display device DD according to the embodiments described above. In addition, some of the individual modules functionally included in one module may be included in the display device DD, while others may be provided separately from the display device DD. For example, the display device DD may include the display module 11, while the processor 12, memory 13, and power module 14 may be provided in the form of other devices within the electronic device 11 rather than in the display device DD.

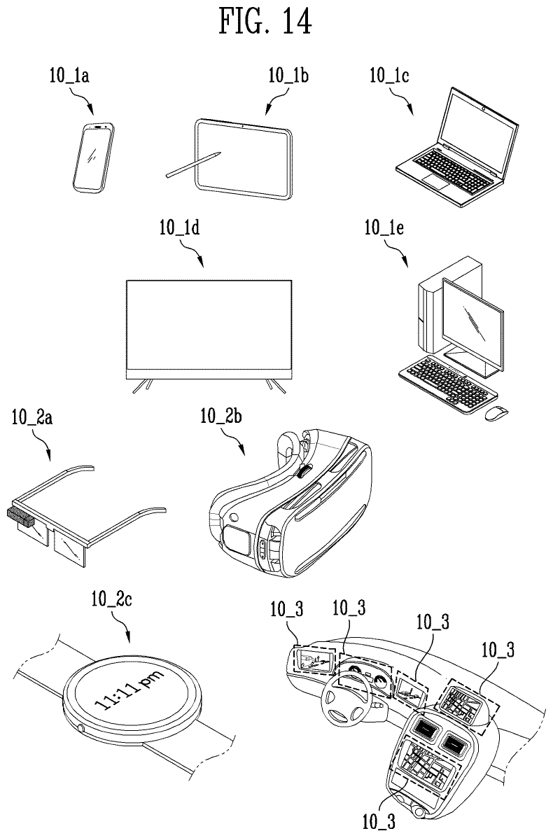

FIG. 14 shows schematic diagrams of electronic devices according to various embodiments. Referring to FIG. 14, various electronic devices to which the display device DD according to the embodiments is applied may include not only image display electronic devices such as a smartphone 10_1a, tablet PC 10_1b, laptop 10_1c, TV 10_1d, desktop monitor 10_1e, but also wearable electronic devices including a display module, such as smart glasses 10_2a, a head-mounted display 10_2b, and a smartwatch 10_2c. Additionally, it may include vehicle electronic devices with a display module, such as a CID Center Information Display arranged on the dashboard, center fascia, or dashboard of a car, or a room mirror display 10_3.

The present disclosure may provide a display device, a resin composition, a method of manufacturing the display device, and an electronic device comprising the display device in which a thickness of a via layer may be suitably controlled.

The present disclosure may provide a display device, a resin composition, a method of manufacturing the display device, and an electronic device comprising the display device in which an interval between alignment electrodes on a via layer may be suitably controlled to have excellent display quality.

Although the present disclosure has been described with reference to embodiments of the disclosure, it will be understood by those skilled in the art or those having ordinary knowledge in the art that the present disclosure may be variously modified and changed without departing from the spirit and the technical scope of the present disclosure set forth in the claims to be described below.

Therefore, the technical scope of the disclosure is not limited to the contents described in the detailed description of the specification, but should be defined by the claims.

What is claimed is:

1. A display device comprising:
a base layer;
a conductive layer on the base layer;
a via layer covering the conductive layer;
an electrode layer disposed on the via layer, and including a first electrode and a second electrode spaced apart from each other by a separation distance; and
a light-emitting element between the first electrode and the second electrode,
wherein the conductive layer and the electrode layer overlap each other in an overlapping area in a plane view,
the via layer has a medium thickness, which is equal to or more than 2 μm, in the overlapping area, and
the separation distance is equal to or more than 3.0 μm.

2. The display device of claim 1, wherein an upper surface of the conductive layer is in direct contact with the via layer.

3. The display device of claim 1, wherein the conductive layer and the electrode layer do not overlap each other in a non-overlapping area in a plane view, and
the via layer includes a flat surface formed in the overlapping area and the non-overlapping area.

4. The display device of claim 1, wherein the medium thickness is in a range of 2 μm to 5 μm.

5. The display device of claim 4, wherein the separation distance is in a range of 3.2 μm to 3.5 μm.

6. The display device of claim 1, further comprising:
a first connection electrode electrically connecting the first electrode to the light-emitting element; and
a second connection electrode electrically connecting the second electrode to the light-emitting element.

7. A method of manufacturing a display device, the method comprising:
arranging a conductive layer on a base layer;
depositing a base via layer which covers the conductive layer and includes a resin composition;
forming a via layer through a polymerization reaction of the base via layer;
patterning a first electrode and a second electrode on the via layer; and
arranging a light-emitting element between the first electrode and the second electrode,
wherein the resin composition includes a resin material including an acrylic resin, a monomer including a multifunctional acrylic monomer, a photoinitiator, and a solvent,
wherein an amount of the resin material is in a range from about 3 wt % to about 10 wt % with respect to an entirety of the resin composition, and
an amount of the monomer is in a range from about 2 wt % to about 5 wt % with respect to the entirety of the resin composition.

8. The method of claim 7, wherein the arranging of the light-emitting elements includes:
supplying ink including the light-emitting element and a solvent onto the base layer;
generating an electric field between the first electrode and the second electrode; and
aligning the light-emitting element between the first electrode and the second electrode based on the electric field.

9. The method of claim 8, wherein the resin material has a molecular weight ranging from about 5,000 g/mol to about 15,000 g/mol in average.

10. The method of claim 8, wherein the monomer includes at least one selected from a group consisting of ethoxylated flrorene type diacrylate, phenylthioethyl acrylate, cumyl phonoxy ethyl acrylate, o-phenylphenoxy ethyl acrylate, and m-phonoxy benzyl acrylate, and an amount of the monomer is in a range from about 2 wt % to about 5 wt % with respect to the entirety of the resin composition.

11. The method of claim 8, wherein the photoinitiator includes at least one selected from a group consisting of a phosphine oxide compound and a metallocene compound, and an amount of the photoinitiator is in a range from about 1 wt % to about 3 wt % with respect to the entirety of the resin composition.

12. The method of claim 8, wherein the resin composition further includes a silicone surfactant, and
the solvent includes at least one selected from a group consisting of methyl 3-methoxypropionate and propylene glycol methyl ether acetate, and an amount of the solvent is in a range from about 82 wt % to about 94 wt % with respect to the entirety of the resin composition.

13. An electronic device, comprising:
a processor configured to provide input image data;
a display device configured to display an image based on the input image data; and
a power supply configured to supply power to the display device,
wherein the display device comprises: a base layer; a conductive layer on the base layer; a via layer covering the conductive layer; an electrode layer disposed on the via layer, and including a first electrode and a second electrode spaced apart from each other by a separation distance; and a light-emitting element disposed on the first electrode and the second electrode and overlapped with a portion of the first electrode and a portion of the second electrode,
the conductive layer and the electrode layer overlap each other in an overlapping area in a plane view,
the via layer has a medium thickness, which is equal to or more than 2 μm, in the overlapping area, and
the separation distance is equal to or more than 3.0 μm.
